(19) United States
(12) Patent Application Publication
(10) Pub. No.: US 2008/0023727 A1
(43) Pub. Date: Jan. 31, 2008

(54) Field effect transistor having its breakdown voltage enhanced

(75) Inventors: Shinichi Hoshi, Tokyo (JP); Masanori Itoh, Tokyo (JP)

Correspondence Address: RABIN & Berdo, PC, 1101 14TH STREET, NW, SUITE 500, WASHINGTON, DC, 20005, US

(73) Assignee: OKI ELECTRIC INDUSTRY CO., LTD., Tokyo (JP)

(21) Appl. No.: 11/878,374

(22) Filed: Jul. 24, 2007

(30) Foreign Application Priority Data
Jul. 27, 2006 (JP) 2006-204694

(51) Int. Cl. H01L 31/072

(52) U.S. Cl. 257/194; 257/E29.253

(57) ABSTRACT

Deterioration of the high frequency characteristics of a field effect transistor is prevented, and the on- and off-gate leakage currents are reduced. A field effect transistor comprises the fourth electrode 126 between the gate electrode 122 and the drain electrode 118. The fourth electrode is formed to satisfy the relationship of 0.25=(FP2−D)/Lgd=0.5, where Lgd represents a distance between the gate and drain electrodes and FP2−D does the distance between the drain and fourth electrodes.

### BACKGROUND OF THE INVENTION

1. Field of the Invention

The present invention relates to a GaN field effect transistor (FET), and more specifically, to a GaN FET having its breakdown voltage enhanced under conductive condition.

2. Description of the Background Art

Among various types of field effect transistors, the MES-FET (MEtal-Semiconductor FET) has its gate electrode, formed by a Schottky barrier, necessarily conducting reverse leakage current normally flowing therefrom, the reverse leakage current being referred to as gate leakage current. Semiconductor devices such as a power FET have the drain electrode thereof to which a high voltage is applied so that a gate-to-source potential difference may act to undesirably increase gate leakage current.

A value of gate voltage at which increased gate leakage current causes the field effect transistor to be destroyed is referred to as “gate breakdown voltage”. In general, a value of gate breakdown voltage when the field effect transistor is in its pinch-off condition, i.e. drain current is cut off, is referred to as “off-breakdown voltage”, and the gate leakage current under that condition is referred to as “off-gate leakage current”. Further, a value of gate breakdown voltage when the field effect transistor has drain current rendered conductive is referred to as “on-breakdown voltage”, and the gate leakage current under the latter condition is referred to as “on-gate leakage current”.

For power FETs, improvement on the off-breakdown voltage has been considered particularly important in order to deliver an increased output power whereas improvement on the on-breakdown voltage is also considered to be one of the important factors influencing the stable operation of field effect transistors. The reasons for this will read as follows. The field effect transistor, while rendered conductive, internally generates heat due to the drain current passing through its channel, resulting in an increase in temperature at the Schottky junction of its gate electrode region. The temperature increase causes the on-breakdown voltage to decrease so that the on-gate leakage current increases, leading to the destruction of the field effect transistor.

Accordingly, in order to provide power FETs with the performance thereof improved, it is crucial how to design power FETs having both of the off- and on-breakdown voltages increased.

As an example of conventional power FET, an AlGaN/GaN-HEMT (High Electron Mobility Transistor) will be described hereinafter with reference to FIG. 6, which is a cross-sectional view schematically showing a conventional AlGaN/GaN-HEMT implemented as a power FET.

In FIG. 6, on a semi-insulating (SI) SiC substrate 100, deposited by MOCVD (Metal Organic Chemical Vapor Deposition) are a buffer layer 102 of GaN or AlN, a channel layer 104 of GaN, an electron source layer 108 of AlGaN, and a cap layer 110 of UID (Un-Internally-Doped)-GaN one over another in this order. Such a structure of deposited layers causes difference in energy bandgap between the GaN channel layer 104 and the AlGaN electron source layer 108 so that a two-dimensional electron gas layer 106 is formed on a portion of the GaN channel layer 104 on the side of the AlGaN electron source layer 108. Into the layered structure, ions of Argon (Ar), etc., are implanted to form isolation regions 112 for isolating the devices from each other. Typically, in the ion implant process, the ions are selectively implanted to a depth ranging from the top surface of the cap layer 110 to under the two-dimensional electron gas layer 106 of the layered structure to thereby compensate for carriers in regions outside the active region of the GaN-HEMT to change that region electrically insulative, thus completing the isolation region 112.

The layered structure fabricated as described above constitutes a semiconductor body 10. Further, the semiconductor body 10 has one surface, which is planar and comprised of top surfaces of the cap layer 110 and isolation region 112, the one surface being referred to as a first principal surface 20.

On the first principal surface 20 of the above-described semiconductor body 10 are formed silicon nitride film 114 as first insulation film, and a source electrode 116 and a drain electrode 118 functioning as ohmic electrodes in ohmic-contact with the first principal surface 20. Then, formed are silicon nitride film 120 functioning as second insulation film overlying the first insulation film and a gate electrode 122 in Schottky-contact with the first principal surface 20. The ohmic electrode is a two-layered structure of Ti and Au films of 15 nm and 200 nm thick, respectively. Further, the gate electrode is a two-layered structure of Ni and Au films of 50 nm and 500 nm thick, respectively.

The AlGaN/GaN-HEMT has primary design rules such that the gate-to-source electrode spacing (Lgs) is 0.75 μm, the gate length (Lg) 0.7 μm, the gate electrode length (GM) 1.0 microns, the gate width (Wg) 10 μm, not shown, and the gate-to-drain electrode spacing (Lgd) 4.9 μm.

Next, the electrical characteristics of the conventional AlGaN/GaN-HEMT having the above-described structure will be described with reference to FIG. 7. FIG. 7 plots the Ids-Vds curves and the gate leakage current behaviors for the conventional AlGaN/GaN-HEMT described with reference to FIG. 6 at an ambient temperature of 200° C. The abscissa or horizontal axis represents source-to-drain voltage Vds (unit: volt V), the left vertical axis represents source-to-drain current Ids (unit: ampere A), and the right vertical axis represents gate leakage current Ig (unit: ampere A) measured at different source-to-drain voltages Vds. In this case, the gate voltage Vg varies from +1 V to −5 V in steps of 1 V, and the gate leakage current Ig is denoted as on-gate leakage current, curve A, at a gate voltage of +1 V and off-gate leakage current, curve B, at a gate voltage of −5 V. At an ambient temperature of 200° C., it has been observed that the AlGaN/GaN-HEMT having such a conventional structure has its on-gate leakage current, curve A, raised higher due to an increase in temperature of its channel region than the off-gate leakage current, curve B.

In order to increase the gate breakdown voltage of conventional field effect transistors having the above-described structure, a field-plate (FP) gate electrode structure has been proposed as an FET structure. For example, J. W. Johnson, et al., “MATERIAL, PROCESS, AND DEVICE DEVELOPMENT OF GaN-BASED HFETs ON SILICON SUBSTRATES” Electrochemical Society Proceedings, June 2004, page 405, and Y.-F. Wu, et al., “Field-plated GaN HEMTs and Amplifiers” CSIC 2005 Digest, pp. 170-172. In the FET structure thus proposed, the overhang portion of a gate electrode on the side of a drain electrode extends in the direction toward the drain electrode, and the structure of this type is known as “gamma gate”.

FIG. 8 illustrates in a cross-sectional structural view a conventional AlGaN/GaN-HEMT with an FP gate for the purpose of describing an FET structure with an FP gate electrode. In this example, the conditions, such as the semiconductor body 10 and the structure of the electrodes formed on the first principal surface, and the design rules are the same as the conventional AlGaN/GaN-HEMT described with reference to FIG. 6. However, it should be specifically featured that, in this example, in order to fabricate an FP electrode structure, use is made, in a gate electrode forming process, of a pattern mask defining the size of an FP electrode and having its overhang portion conforming to the FP electrode to extend toward the drain region over the silicon nitride film 120 functioning as second insulation film to thereby fabricate the FP electrode 124. The FP electrode 124 is formed simultaneously with the gate electrode, and therefore is a layered structure of Ni and Au films of 50 nm and 500 nm thick, respectively, as in the case with the conventional AlGaN/GaN-HEMT described earlier.

The important design rules of the AlGaN/GaN-HEMT with the FP electrode are such that the gate-to-source electrode spacing (Lgs) is 0.75 μm, the gate length (Lg) 0.7 μm, the gate electrode length (GM) 1.0 μm, the gatewidth (Wg) 10 μm, not shown, and the gate-to-drain electrode spacing (Lgd) 4.9 μm.

With the use of the gate electrode 125 having such an FP electrode structure, an electric field otherwise concentrated on the edge portion of the gate electrode on the side of a drain region will be dispersed, thereby increasing the off-breakdown voltage of the AlGaN/GaN-HEMT with the FP electrode. For example, J. W. Johnson, et al., stated above reports that an FP electrode is formed to a length of about 1.2 μm and then off-gate leakage current is reduced to one-third or less compared to an ordinary AlGaN/GaN-HEMT without having an FP electrode.

FIG. 9 plots how gate leakage current varies depending on the length LFP of an FP electrode of the AlGaN/GaN-HEMT provided with the FP electrode described with reference to FIG. 8 and operating at an ambient temperature of 200° C. The abscissa axis represents the length of an FP electrode (unit: μm) and the vertical axis represents gate leakage current per gate width Ig (unit: mA/mm). On-gate leakage current curve C shows how gate current Ig varies with gate voltage Vg=+1 V and source-drain voltage Vds=60 V. Further, off-gate leakage current curve D shows how gate current Ig varies with Vg=−5 V and Vds=60 V.

As seen from FIG. 9, if the upper limit of allowable gate leakage current Ig is designed equal to about 1 mA/mm, it is then found that the off-gate leakage current, curve D becomes below the upper limit already when the length of the FP electrode is about 0.25 μm or more, whereas the off-gate leakage current, curve C becomes below the upper limit only when the length of the FP electrode is about 2 μm or more.

However, the FP electrode is a portion of the gate electrode that extends toward the drain electrode, and therefore causes the gate-to-drain capacitance Cgd to increase, thereby degrading the frequency characteristics of the field effect transistor. Particularly, such increase in capacitance Cgd reduces the power gain of the field effect transistor. Accordingly, in the field effect transistor having an FP electrode, a tradeoff relationship is incurred between the length of the FP electrode and the frequency characteristics.

Another example of the GaN FET is also disclosed, for example, by U.S. patent application publication No. US 2006/0043415 A1 to Okamoto, et al. In Okamoto et al., an electric field control electrode controllable independent of a gate voltage is disposed between a gate and a drain electrode. In the proposed structure, the gate-to-drain capacitance Cgd is reduced to improve the frequency characteristics of the field effect transistor. Moreover, according to Okamoto, et al., stated earlier, the edge of the electric field control electrode is extended toward the drain region to allow the field effect transistor to enhance the suppression of current collapse. However, the parasitic capacitance attributable to the field control electrode increases, thereby degrading the frequency characteristics of the field effect transistor. Additionally, although the off-breakdown voltage of the field effect transistor increases depending on where the electric field control electrode is disposed, the provision of the control electrode does not necessarily result in a sufficient increase in on-breakdown voltage of the field effect transistor. Okamoto, et al., further refers to the width of the electric field control electrode. However, it does not teach at which position the electric field control electrode is formed between the gate and drain.

As described above, in order to increase both the on-breakdown voltage and the off-breakdown voltage for an FP electrode configuration, the width of the FP electrode has to be increased, which results in an increase in gate-to-drain capacitance Cgd, thereby degrading the frequency characteristics of the field effect transistor.

Further, Okamoto, et al., is silent about a location at which the electric field control electrode is formed for the electric field control electrode configuration. Moreover, the provision of the electric field control electrode near the gate electrode effectively increases an off-breakdown voltage, indeed. However, such a provision would certainly not increase an on-breakdown voltage. Additionally, although Okamoto, et al., teaches the edge of the electric field control electrode is extended toward the drain electrode to allow the field effect transistor to present the suppression of current collapse, the parasitic capacitance attributable to the electric field control electrode increases, thereby degrading the frequency characteristics of the field effect transistor, as is the case with the FP electrode configuration. Accordingly, also in the electric field control electrode configuration, a tradeoff relationship is involved between an increase in width of the electric field control electrode and the frequency characteristics of the field effect transistor.

### SUMMARY OF THE INVENTION

It is an object of the invention to provide a field effect transistor with the degradation in frequency characteristics minimized and the on- and off-gate leakage current decreased.

In order to achieve the above object, the field effect transistor having the following features is proposed according to the invention. More specifically, the field effect transistor has its electric field concentration region established in an area of a Schottky barrier gate away from a drain region.

According to the invention, a field effect transistor comprising a source electrode, a gate electrode and a drain electrode formed on a semiconductor substrate further comprises an additional fourth electrode formed on the substrate between the gate electrode and the drain electrode, and the additional electrode is disposed to satisfy the ratio of a distance between the drain electrode and the additional electrode to a distance between the gate electrode and the drain electrode falls in a range from 0.25 to 0.5, both inclusive.

According to an aspect of the invention, the additional electrode may be a field pinning plate electrode, which may be defined as “FP2 electrode”. The FP2 electrode is the fourth electrode intentionally positioned remotely from the edge of Schottky gate electrode on the side of the drain electrode to cause an electric field to be concentrated on the fourth electrode.

According to another aspect of the invention, the field effect transistor may comprise an insulative layer under the gate electrode on the substrate to form a MIS (Metal Insulator Semiconductor) structure.

According of a further aspect of the invention, the field effect transistor may be an AlGaN/GaN-HEMT (High Electron Mobility Transistor).

According to the invention, the field pinning plate electrode, or FP2 electrode, is formed as the fourth electrode intentionally positioned remotely from an edge of the Schottky gate electrode on the side of the drain electrode to cause an electric field to be concentrated on the field pinning electrode. As a result, advantageously, the on- and off-gate leakage currents of the field effect transistor are both reduced, while the frequency characteristics of the transistor is not degraded.

According to the invention, the FP2 electrode, i.e. the electric field concentration region is intentionally positioned remotely from the edge of the Schottky gate electrode on the side of a drain electrode, and therefore, advantageously, even when the field effect transistor has a gate insulation film formed to a smaller thickness, any reduction in breakdown strength of insulation is eliminated.

According to the invention, the AlGaN/GaN-HEMT provides the same benefits as with the HEMT.

### BRIEF DESCRIPTION OF THE DRAWINGS

The objects and features of the present invention will become more apparent from consideration of the following detailed description taken in conjunction with the accompanying drawings in which:

FIG. 1 is a schematic cross-sectional view illustrating the structure of an AlGaN/GaN-HEMT in accordance with an illustrative embodiment of the present invention;

FIG. 2 plots the characteristics of the AlGaN/GaN-HEMT according to the illustrative embodiment shown in FIG. 1;

FIG. 3 plots the R versus Ig behavior for the AlGaN/GaN-HEMT according to the illustrative embodiment;

FIG. 4 schematically shows the electric potential distribution in the AlGaN/GaN-HEMT according to the illustrative embodiment;

FIG. 5 is a cross-sectional view, like FIG. 1, illustrating the structure of a MIS type of AlGaN/GaN-HEMT in accordance with an alternative embodiment of the invention;

FIG. 6 is a schematic cross-sectional view of the structure of a conventional AlGaN/GaN-HEMT;

FIG. 7 plots the transistor characteristics of the conventional AlGaN/GaN-HEMT shown in FIG. 6;

FIG. 8 is a schematic cross-sectional view illustrating the structure of the conventional AlGaN/GaN-HEMT with an FP electrode; and

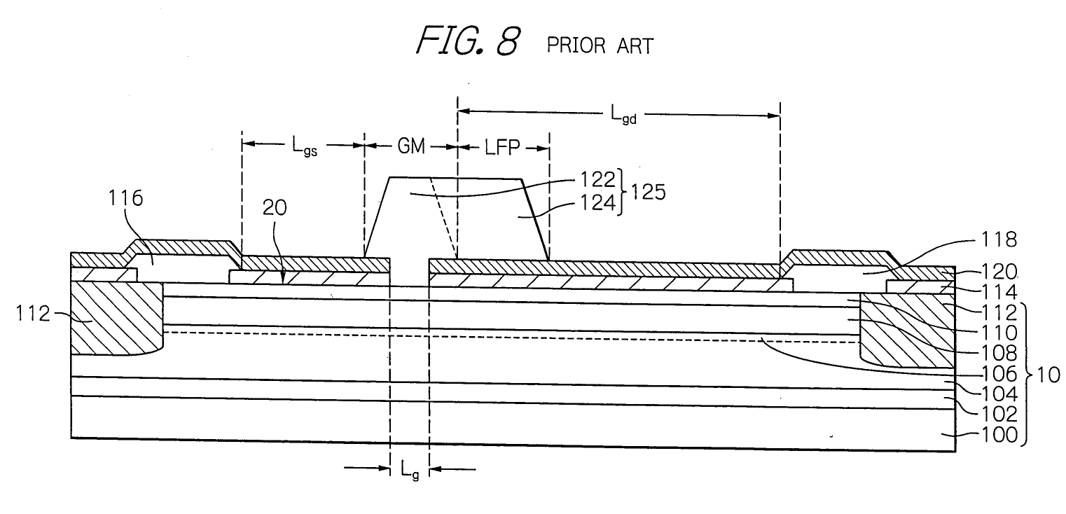

FIG. 9 plots the FP electrode length versus Ig behavior for the conventional AlGaN/GaN-HEMT with the FP electrode shown in FIG. 8.

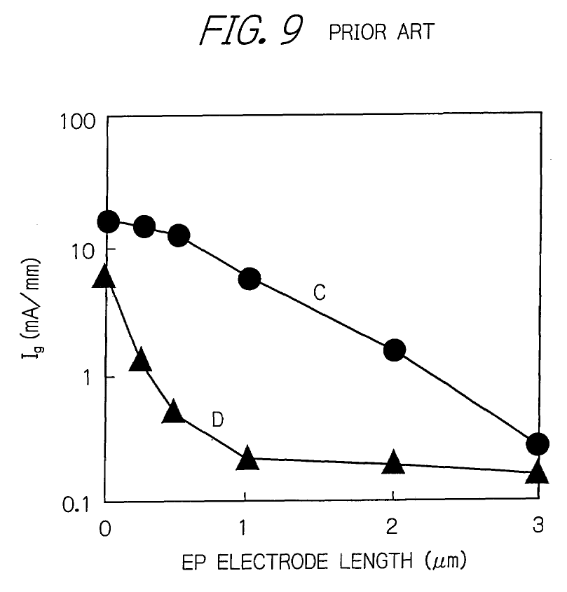

### DESCRIPTION OF THE PREFERRED EMBODIMENTS

Now, with reference to the accompanying drawings, preferred embodiments of a field effect transistor (FET) according to the present invention will be described in detail. Those drawings are simplified schematic representations intended to generally illustrate the shape, size, and positional relationships of the various structural components to the extent that the present invention can be understood. The materials used, numerical conditions, and so forth given below are nothing but examples in the scope included in the essence of the invention, and the present invention is not limited to the specific description and illustration. Also, in order to make the figures easier to understand, the figures include portions without hatching to indicate across-section. The illustrative embodiments will be directed to an AlGaN/GaN-HEMT (High Electron Mobility Transistor) as an example of a field effect transistor.

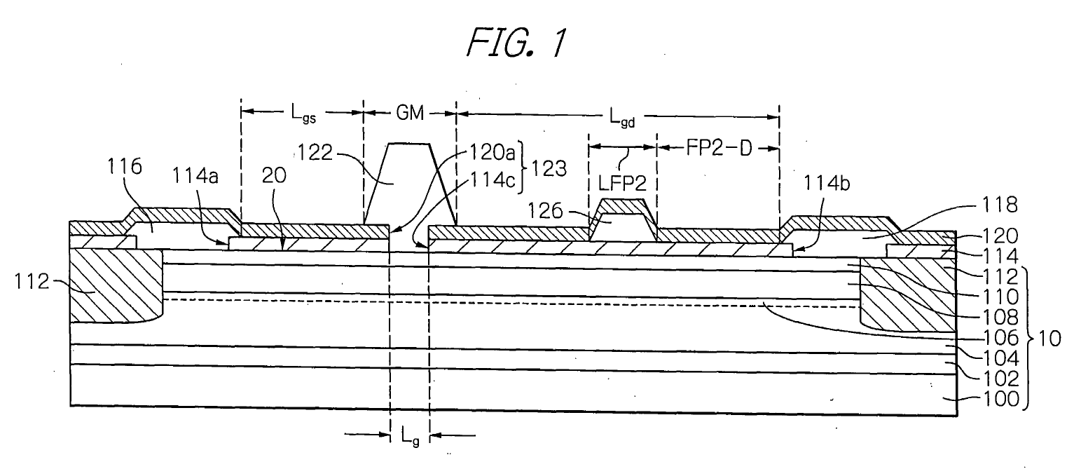

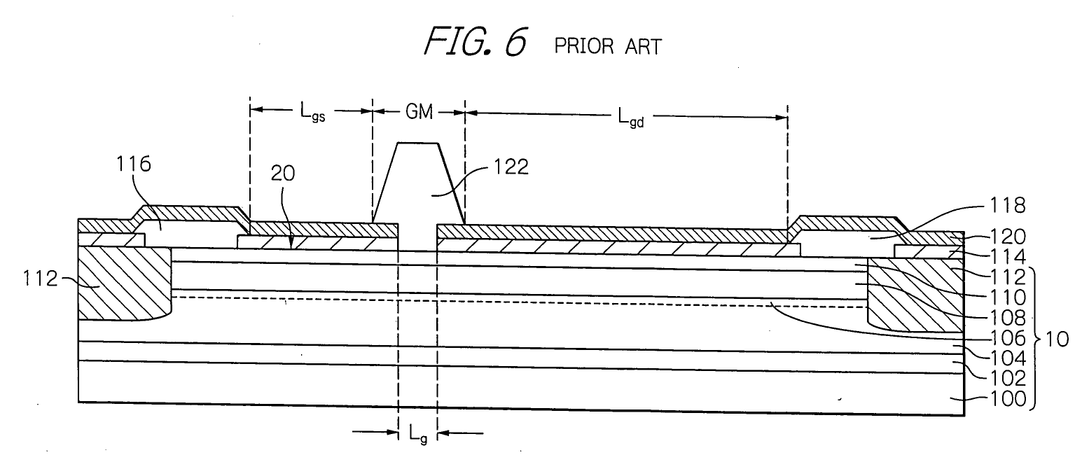

FIG. 1 is a structural cross-sectional view of an AlGaN/GaN-HEMT in accordance with an illustrative embodiment of the invention. Description will first be made referring to FIG. 1. The illustrative embodiment include a semiconductor body 10, which includes a lamination or multiple layered structure similar to the conventional AlGaN/GaN-HEMT shown in FIG. 6. In the following, therefore, like elements and parts are designated by the same reference numerals, and those not directly pertinent to understanding the invention will not repetitively be described merely for simplicity except otherwise necessity.

In the illustrative embodiment, on the first principal surface 20 of the semiconductor body 10, silicon nitride film 114 as an example is deposited to a thickness of 50 nm as the first insulation film. The silicon nitride film 114 functioning as the first insulation film has openings 114a, 114b, and 114c formed therein for exposing therethrough part of the first principal surface 20. Further, as electrodes in ohmic contact with the part of the first principal surface 20 formed by the cap layer 110 and exposed through the openings 114a and 114b, formed are a source ohmic electrode 116 and a drain ohmic electrode 118.

In the illustrative embodiment, between the source electrode 116 and drain electrode 118, an additional electrode 126 is formed as the fourth electrode. The fourth electrode 126 is referred to as field pinning plate or simply FP2 electrode. The FP2 electrode 126 is formed on the silicon nitride film 114 as the first insulation film, for example, between a gate electrode 122 and the drain electrode 118.

Over the silicon nitride film 114 functioning as the first insulation film, the source electrode 116 and the drain electrode 118, silicon nitride film 120 is formed to a thickness of 50 nm as the second insulation film. The silicon nitride film 120 has an opening 120a cut which are identical in shape and size to, and in communication with, the opening 114c formed in the silicon nitride film 114 functioning as the first insulation film, thus allowing both of the openings to form a single opening 123 together. As an electrode made in Schottky contact with the part of the first principal surface 20 exposed through that opening 123 and formed by the cap layer 110, the gate electrode 122 is formed.

For example, the ohmic electrodes such as the source and drain electrodes 116 and 118 are a two-layered structure of Ti and Au films of 15 nm and 200 nm thick, respectively. Further, for example, the gate electrode 122 is a two-layered structure of Ni and Au films of 50 nm and 500 nm thick, respectively. As another example, the FP2 electrode 126 is a three-layered structure of Ti, Pt and Au films of 50 nm, 25 nm and 50 nm thick, respectively.

Now, the design rules of the AlGaN/GaN-HEMT with the FP2 electrode according to the illustrative embodiment are such that, for example, the gate-to-source electrode spacing (Lgs) is 0.75 μm, the gate length (Lg) 0.7 μm, the gate electrode length (GM) 1.0 μm, the gate width (Wg) 10 μm, not shown, and the gate-to-drain electrode spacing (Lgd) 4.0 μm. Further, the FP2 electrode has its length equal LFP2 to, e.g. 0.5 μm. The spacing between the edge of the FP2 electrode on the side of the drain electrode and the edge of the drain electrode on the side of the FP2 electrode will simply be referred to as “FP2-D” hereinafter. Further, the FP2 electrode 126 is wired so as to be in common to the source electrode 116.

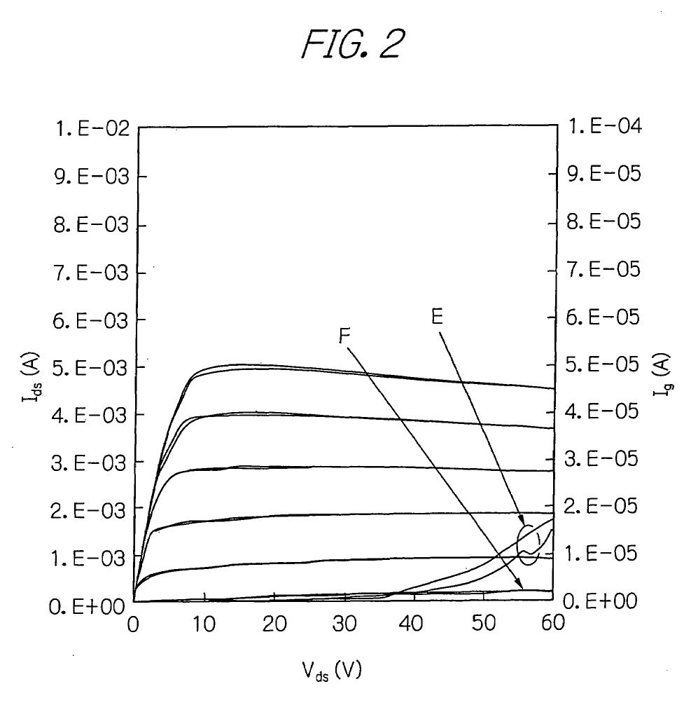

Well, the electrical characteristics of the AlGaN/GaN-HEMT having the FP2 electrode according to the illustrative embodiment under the design rules described above will be described with reference to FIG. 2. FIG. 2 plots the Ids vs Vds characteristics and the gate leakage current behaviors at a temperature of 200° C. for the AlGaN/GaN-HEMT having the FP2 electrode described with reference to FIG. 1. In the figure, as apparent, those curves are looped due to the way of measurement.

FIG. 2 shows results of measurements on the AlGaN/GaN-HEMT where a ratio R of FP2-D to Lgd, i.e. (FP2-D)/Lgd, is equal to 0.5. The abscissa or horizontal axis represents the source-to-drain voltage Vds (unit:volt V), the left vertical axis represents the source-to-drain current Ids (unit: ampere A), and the right vertical axis represents the gate leakage current Ig (unit: ampere A) measured at the different source-to-drain voltages Vds. In this case, the gate voltage Vg varies from +1 V to −5 V in steps of 1 V, while the gate leakage current Ig is denoted as on-gate leakage current, curve E at a gate voltage of +1 V and the off-gate leakage current, curve F at a gate voltage of −5 V. It is noted that the off-gate leakage current curve F overlaps the Ids-Vds curve.

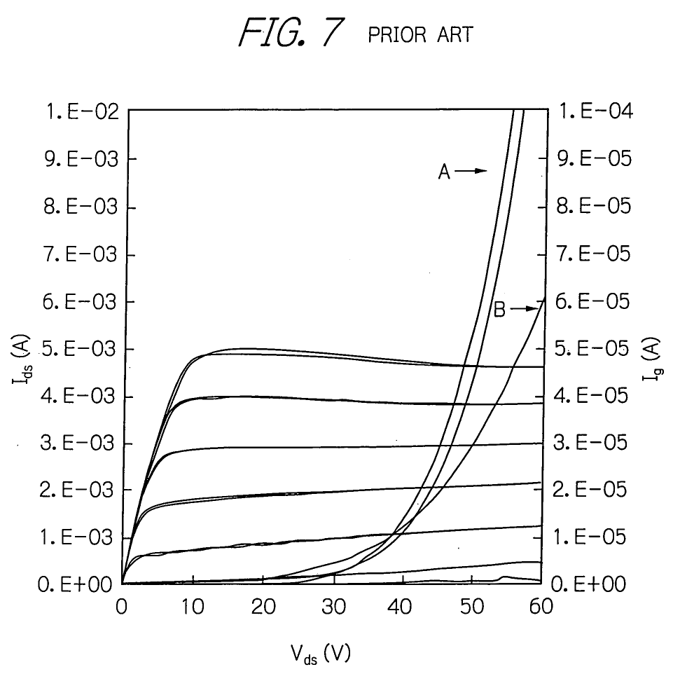

Those results reveal that at the temperature of 200° C., in comparison to the characteristics of the conventional AlGaN/GaN-HEMT plotted in FIG. 7, the on-gate leakage current, curve E, and the off-gate leakage current, curve B, are both reduced, thus demonstrating the beneficial effects of the inventive electrode design with the FP2 electrode. Particularly, the gate-off leakage current, curve B, is quite small. That is, the provision of the FP2 electrode substantially increases the gate breakdown voltage of the AlGaN/GaN-HEMT.

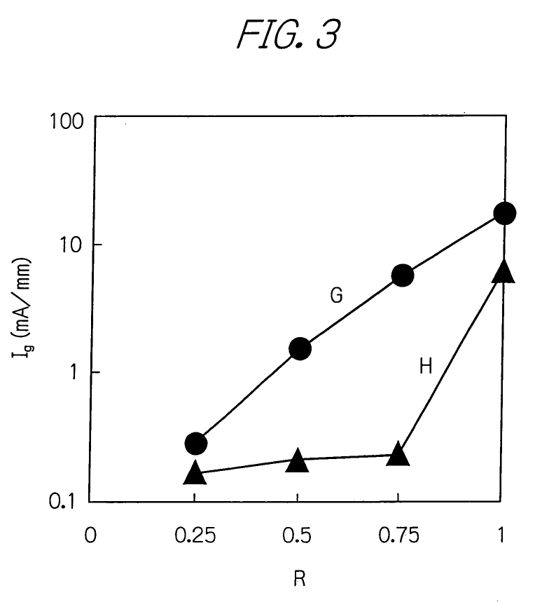

FIG. 3 shows how the gate leakage current of the AlGaN/GaN-HEMT having the FP2 electrode described with reference to FIG. 1 varies with the FP2-D at the temperature of 2000C. The abscissa axis represents the ratio R of the FP2-D to Lgd, i.e. (FP2-D)/Lgd and the vertical axis represents the gate leakage currents Ig in the form of current per gate width, mA/mm. In this case, the FP2 electrode is connected in common to the source electrode having its electrical potential fixed to 0 V. Curve G for the on-gate leakage current shows how the gate current Ig varies measured at the gate voltage Vg=+1 V and the source-drain voltage Vds=60 V. Further, curve H for the off-gate leakage current shows how the current Ig varies measured at Vg=−5 V and at Vds=60 V. It should be noted that the ratio R being closer to unity means the edge of the FP2 electrode on the side of the drain electrode resides closer to the gate electrode while the ration R being equal to unity means the FP2 electrode is not provided. In contrast, the ration R being closer to null means the edge of the FP2 electrode on the side of the drain electrode is provided closer to the drain electrode.

As shown in FIG. 3, if the upper limit of the allowable gate leakage current Ig is equal to about 1 mA/mm, it is then found that the off-gate leakage current, curve H, goes below the upper limit already when the ratio R of FP-D to Lgd is equal to or less than 0.75, whereas the off-gate leakage current, curve G, goes below the upper limit only when the ratio R of FP-D to Lgd is equal to or less than 0.5. Further, when the ratio R is less than 0.25, electrostatic breakdown occurred at the edge portion of the FP2 electrode on the side of the drain electrode.

A conclusion resulting from the above findings is that the AlGaN/GaN-HEMT with the FP2 electrode structure according to the invention requires that the FP2 electrode be provided with the ratio R of FP-D to Lgd equal to or more than 0.25 and not more than 0.5 in order to control or suppress the off- and on-gate leakage currents. Further, since the length LFP2 of the FP2 electrode is fixed, degradation in frequency characteristics of the transistor due to parasitic capacitance component is not observed.

From the above, it has been understood important that, according to the illustrative embodiment, the on-gate leakage current varies depending on the position of the edge of the FP2 electrode on the side of the drain electrode, i.e. the value of the ratio R, and hence the FP2 electrode is formed with the value of the ration R falling in the range from 0.25 to 0.5, both inclusive. In particular, when a higher voltage is applied between the gate and drain electrodes, an electric field induced is concentrated limitedly to the region between the FP2 and drain electrodes, which means it is important for an electric field concentration region to be far away from the edge of the gate electrode on the side of the drain electrode.

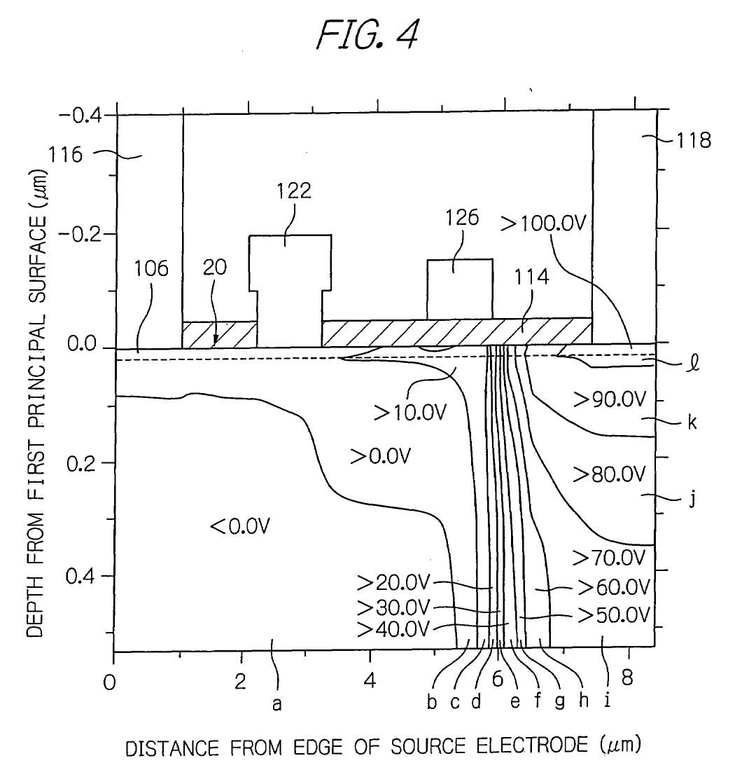

The above ideas will further be described with reference to FIG. 4. FIG. 4 depicts an electric potential distribution, simulated with a device simulator, across the cross section of the AlGaN/GaN-HEMT having the FP2 electrode 126 shown in FIG. 1 and configured to exhibit the value R equal to 0.5. The bias conditions used for the simulation are such that the drain voltage Vds is equal to 100 V and the gate voltage Vg+1 V.

In FIG. 4, the vertical axis represents, in units of μm, a depth in the direction from the first principal surface 20 of the semiconductor body 10 to the semi-insulating (SI)-SiC substrate 100, and the abscissa axis represents, also in units of μm, a distance in the direction parallel to the first principal surface 20 from the end of the source electrode 116 to the drain electrode 118 in the AlGaN/GaN-HEMT with the FP2 electrode. Beneath the first principal surface 20 is formed a two-dimensional electron gas layer 106, and between the source electrode 116 and drain electrode 118 are formed the gate electrode 122 and FP2 electrode 126. In this case, the ratio R of FP2-D to Lgd is equal to 0.5. Further, between the FP2 electrode and first principal surface is formed the silicon nitride film 114 as the first insulation film.

When a drain voltage Vds=100 V is applied, an electric potential distribution is made in such a way that the potential ranges from 0 V on the source electrode 116 to 100 V on the drain electrode 118. The potential distribution is divided into twelve zones from the region “a” on the side of the source electrode to the region “l” just below the drain electrode 118. The electric potentials of those regions are as follows. The potential of the region “a” is less than 0.0 V. The potential of the region “b” is more than 0.0 V. The potential of the region “c” is more than 10.0 V. The potential of the region “d” is more than 20.0 V. The potential of the region “e” is more than 30.0 V. The potential of the region “f” is more than 40.0 V. The potential of the region “g” is more than 50.0 V. The potential of the region “h” is more than 60.0 V. The potential of the region “i” is more than 70.0 V. The potential of the region “j” is more than 80.0 V. The potential of the region “k” is more than 90.0 V. The potential of the region “1” is more than 100.0 V.

A conclusion resulting from the simulation work is that when the equipotential regions “d” through “j”, i.e. the equipotential zones of 20.0 V through 80 V are close together on the edge of the FP2 electrode 126 on the side of the drain electrode 118. In particular, the transitional points of electric potential are far away from the edge of the gate electrode 122 on the side of the drain electrode, i.e. relatively close together at the edge of the FP2 electrode 126 on the side of the drain electrode, thereby avoiding the electric field concentration on the edge of the gate electrode.

An alternative embodiment of the present invention will be described which is directed to a MIS (Metal Insulator Semiconductor) type of AlGaN/GaN-HEMT having an FP2 electrode functioning as the fourth electrode.

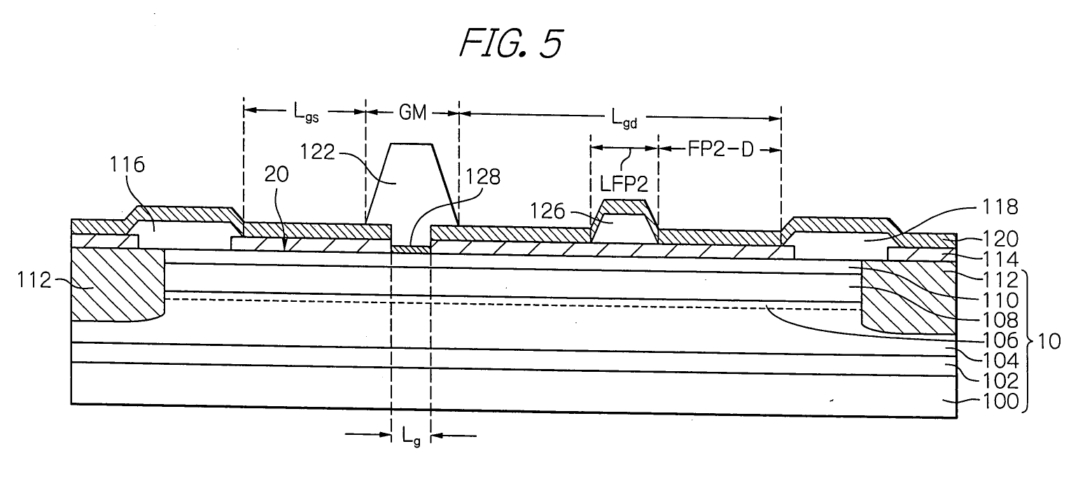

FIG. 5 is a cross-sectional view illustrating the structure of the MIS type of AlGaN/GaN-HEMT having the FP2 electrode. The configuration of the semiconductor body 10 is the same as the conventional AlGaN/GaN-HEMT described with reference to FIG. 6, and therefore, the description thereof will not be repeated. Further, the electrical insulation films and electrodes formed on the semiconductor body 10 may be identical to those of the first embodiment described with reference to FIG. 1. The alternative embodiment is, however, different from the first embodiment in that silicon nitride film with a thickness of 2.5 nm is formed as gate insulation film 128 between the gate electrode 122 and the first principal surface 20 of the cap layer 110, thus establishing the gate structure of a MIS type of transistor. The primary design rules of the transistors of the illustrative embodiment may be identical to the first embodiment, and thus the description thereof will not be repetitive.

Like the first embodiment previously described, the MIS type of AlGaN/GaN-HEMT of the alternative embodiment also has the FP2 electrode 126 formed therein, and thus the electric field is concentrated on the edge of the FP2 electrode 126 on the side of the drain electrode. Accordingly, the MIS type of field effect transistor having the gate insulation film 128 formed just below the gate electrode 122 has a higher insulation breakdown voltage than the MIS type of field effect transistor without such an FP2 electrode corresponding to the electrode 126. Thus, it can be concluded that the provision of the FP2 electrode 126 allows the MIS type of field effect transistor having the gate insulation film 128 with a thickness of as thin as 2.5 nm to eliminate any reduction in insulation breakdown strength.

As described so far, according to the alternative embodiment, in the MIS type of AlGaN/GaN-HEMT having the FP2 electrode formed therein, the transitional points of electric potential lay relatively close together at the edge of the FP2 electrode on the side of the drain electrode, when a large voltage is applied to the drain electrode, in the same manner as the electric potential distribution previously described referring to FIG. 4. Accordingly, an electric field applied to the portion of the MIS structure just below the gate electrode is reduced, allowing the MIS type of field effect transistor having the MIS structure to accomplish a greater insulator breakdown voltage. Further, it is more advantageous that the FP2 electrode is formed in a position satisfying the relationship of 0.25=R=0.5. This is because the strength of an electric field applied across the MIS type of field effect transistor in the alternative embodiment depends upon the value of the ratio R similarly to the first embodiment. Further, since the length of the FP2 electrode is fixed, degradation in frequency characteristics of the transistors due to parasitic capacitance component is not observed.

The entire disclosure of Japanese patent application No. 2006-204694 filed on Jul. 27, 2006, including the specification, claims, accompanying drawings and abstract of the disclosure is incorporated herein by reference in its entirety.

While the present invention has been described with reference to the particular illustrative embodiments, it is nottoberestrictedbytheembodiments. Itistobeappreciated thatthoseskilledintheartcanchangeormodifytheembodiments without departing from the scope and spirit of the present invention.

What is claimed is:

1. A field effect transistor comprising a source electrode, a gate electrode and a drain electrode formed on a semiconductor substrate,
said transistor further comprising an additional fourth electrode formed on the substrate between the gate electrode and the drain electrode,
said additional electrode being disposed to satisfy a ratio of a distance between the drain electrode and said additional electrode to a distance between the gate electrode and the drain electrode falls in a range from 0.25 to 0.5, both inclusive.

2. The field effect transistor in accordance with claim 1, wherein said additional electrode is a field pinning plate electrode.

3. The field effect transistor in accordance with claim 1, further comprising an insulative layer under the gate electrode on the substrate to form a MIS (Metal Insulator Semiconductor) structure.

4. The field effect transistor in accordance with claim 1, wherein said field effect transistor is an AlGaN/GaN-HEMT (High Electron Mobility Transistor).
